(19) United States
(12) Patent Application Publication
(10) Pub. No.: US 2016/0020394 A1
(43) Pub. Date: Jan. 21, 2016

(54) BACKPLANE PRINTING PROCESS AND DEVICE

(71) Applicant: E I DU PONT DE NEMOURS AND COMPANY, Wilmington, DE (US)

(72) Inventor: CHARLES D. LANG, GOLETA, CA (US)

(21) Appl. No.: 14/802,652

(22) Filed: Jul. 17, 2015

Related U.S. Application Data
(60) Provisional application No. 62/026,354, filed on Jul. 18, 2014.

(51) Int. Cl. H01L 51/00; H01L 27/32; H01L 51/56

(52) U.S. Cl. CPC H01L 51/0004; H01L 51/56; H01L 27/32; H01L 51/5012

(57) ABSTRACT

A printing operation using a backplane having at least one topographical feature located in a non-display area of the backplane. Continuous liquid printing produces layers contacting the at least one topographical feature, and these layers each exhibit uniform thickness. Non-display areas of the backplane are subsequently removed after completion of the printing operation to yield uniform layers within display areas of the backplane.

### BACKGROUND OF THE INVENTION

1. Field of the Invention

This invention relates to a printing process, and resultant electronic device, for depositing a liquid composition on a surface. In particular, depositing the liquid composition containing an organic semiconductor material on a backplane. More particularly, physical containment of a layer of organic semiconductor material using at least one topographical feature located on a non-display area of the backplane. The backplane containing display areas in addition to the non-display areas. The topographical features promote uniform thickness of layers deposited via continuous liquid techniques. The display areas of the backplane can contain one or more electrodes to produce electronic devices. This process mitigates edge effects associated with deposition of continuous liquid compositions using topographical features for physical containment. Edge effects are reduced, resulting in more uniformity in the thickness dimension of the deposited organic semiconductor material.

2. Description of the Related Art

An electronic device can include a liquid crystal display (“LCD”), an organic light-emitting diode (OLED) display, or the like. The manufacture of electronic devices may be performed using solution deposition techniques. One process of making electronic devices is to deposit organic layers over a substrate, also referred to as a backplane when containing electronic elements, by printing (e.g., ink-jet printing, continuous printing, etc.). In a printing process, the liquid composition, also called ink, being printed includes an organic material in a solution, dispersion, emulsion, or suspension with an organic solvent, with an aqueous solvent, or with a combination of solvents. After printing, the solvent(s) is(are) evaporated and the organic material remains to form an organic layer for the electronic device.

OLED devices utilizing one or more layers of organic semiconductor materials laminated with other supporting layers and sandwiched by two electrodes are used in many different kinds of electronic equipment.

Several methods for providing ink containment for OLED devices are described in the literature. These are based on containment structures, surface tension discontinuities, and combinations of both. Containment structures within display areas of the backplane are geometric obstacles to spreading: pixel wells, banks, etc. In order to be effective these structures must be large, comparable to the wet thickness of the deposited materials. When emissive ink is printed into these structures it wets onto the structure surface, so thickness uniformity is reduced near the structure. Therefore the structure must be moved outside the emissive “pixel” region, but still within the display area of the backplane, so the non-uniformities are not visible in operation. Due to limited space on the display (especially high-resolution displays) this reduces the available emissive area of the pixel. Practical containment structures generally have a negative impact on quality when depositing material within display areas of the backplane.

Each organic semiconductor material can be carried in a liquid composition. During manufacture of a device each liquid composition is dispensed from a dedicated nozzle assembly. Each nozzle assembly dispenses liquid and deposits that liquid along a longitudinal path that extends across the backplane of the device. The nozzle assemblies can be located within a printhead, and the printhead travels in a linear path in a first or forward direction, in addition to a second or reverse direction, while printing the liquid composition on the backplane.

Liquid printing can be conducted in either non-continuous or continuous operation as disclosed in the prior art. The deposition of the liquid composition in a continuous web, or blanket, operation leads to non-uniformities in the resultant layer upon drying on the backplane. Specifically, as the liquid composition dries solvent diffuses into the surrounding environment. Because of the increased surface area at the edges of the continuous web, the edges dry more rapidly than the center portion of the continuous web. This can lead to retraction of the continuous web for compositions having high contact angle, or expansion of the continuous web for compositions having low contact angle. The concept of contact angle is explained later in this specification. This retraction or expansion of the continuous web results from surface tension gradients, where retraction or expansion is from the initial contact area with the backplane.

One approach to minimize the retraction or expansion of the continuous web is the use of different solvents to either slow or accelerate drying and reduce surface tension gradients, but this approach is not very practical because of negative impacts on factors such as production efficiency and device performance.

The location and control of the edge of the continuous web is important to establish uniform thickness across the continuous web, resulting in a smooth and uniform surface of the resulting organic semiconductor layer(s). These edge effects are a continuing problem, and the proposed solutions have not met the required level of uniformity for these layers.

In view of the foregoing it is believed additional improvement is required to optimize organic electronic devices.

### SUMMARY OF THE INVENTION

The present invention is directed to a process to overcome limitations inherent to printing a liquid composition in a continuous web onto a backplane. The process and device includes, for example, a backplane with a surface having display and non-display areas, and at least one topographical feature located on the non-display area of the backplane. The liquid composition is deposited in a continuous web and contacts the topographical feature, upon drying the edge feature of the dried composition has a thickness within 20 percent of the average thickness of the dried composition.

The process and device contains at least the following elements.

A printing process comprising:
providing a backplane having a top surface with display areas and non-display areas, the backplane also having a first side and a second side;
providing at least one topographical feature in the non-display area on the first side of the backplane; and
depositing an active material on display areas and at least a portion of the non-display areas, wherein the active material contacts the topographical feature to produce an edge thickness of the active material within plus-or-minus 20 percent of average thickness of active material.

In at least one embodiment the printing process further comprising a second topographical feature in the non-display area of the second side of the backplane.

In at least one embodiment the printing process further comprising a third topographical feature in the non-display area at a front side of the backplane.

In at least one embodiment the printing process further comprising a fourth topographical feature in the non-display area at a back side of the backplane.

In at least one embodiment the printing process employs a continuous printer to deposit the active material.

In at least one embodiment the continuous printer is a slot die coater.

In at least one embodiment the first and second topographical features are parallel to one another, and distance D defines the distance between inner edges of the first and second topographical features.

In at least one embodiment the slot die coater deposits a web of the active material, wherein the web has width W upon contact with the backplane. In various embodiments W can be equal, greater than, or less than D

An electronic device comprising:
a backplane having a top surface with display areas and non-display areas, the backplane also having a first side and a second side;
at least one topographical feature in the non-display area on the first side of the backplane; and
an active material covering display areas and at least a portion of the non-display areas, wherein the active material contacts the topographical feature to produce an edge thickness of the active material within plus-or-minus 20 percent of average thickness of active material.

In at least one embodiment the electronic device further comprising a second topographical feature in the non-display area of the second side of the backplane.

In at least one embodiment the electronic device wherein the non-display areas are removed from the backplane.

### BRIEF DESCRIPTION OF THE DRAWINGS

The invention will be more fully understood from the following detailed description, taken in connection with the accompanying drawings, which form a part of this application and in which:

FIG. 1 represents an embodiment of the present invention with a backplane having display areas and non-display areas with a first and a second topographical feature located in first and second non-display areas.

FIG. 2 represents an embodiment of the present invention with a continuous printer depositing a liquid composition onto the backplane.

FIG. 3 represents an embodiment of the present invention with a third and a fourth topographical feature located in non-display areas.

FIG. 4 illustrates edge effects producing a thin edge of a dried layer.

FIG. 5 represents edge effects producing a thick edge of a dried layer.

FIG. 6 represents an embodiment of the present invention using a topographical feature and resultant dried layer.

FIG. 7 represents contact angle between a surface and a liquid droplet.

Skilled artisans appreciate that objects in the figures are illustrated for simplicity and clarity and have not necessarily been drawn to scale. For example, the dimensions of some of the objects in the figures may be exaggerated relative to other objects to help to improve understanding of embodiments.

### DETAILED DESCRIPTION OF THE INVENTION

Many aspects and embodiments have been described above and are merely exemplary and not limiting. After reading this specification, skilled artisans appreciate that other aspects and embodiments are possible without departing from the scope of the invention.

Other features and benefits of any one or more of the embodiments will be apparent from the following detailed description, and from the claims.

### DEFINITIONS AND CLARIFICATION OF TERMS

Before addressing details of embodiments described below, some terms are defined or clarified.

The term “active” when referring to a layer or material, is intended to mean a layer or material that exhibits electronic or electro-radiative properties. In an electronic device, an active material electronically facilitates the operation of the device. Examples of active materials include, but are not limited to, materials which conduct, inject, transport, or block a charge, where the charge can be either an electron or a hole, and materials which emit radiation or exhibit a change in concentration of electron-hole pairs when receiving radiation. Examples of inactive materials include, but are not limited to, planarization materials, insulating materials, and environmental barrier materials.

The term “backplane” is used to describe a substrate containing electronic elements.

The term “continuous” and its variants are intended to mean substantially unbroken. In one embodiment, continuously printing is printing using a substantially unbroken stream of a liquid or a liquid composition, as opposed to a depositing technique using drops. In another embodiment, extending continuously refers to a length of a layer, member, or structure in which no significant breaks in the layer, member, or structure lie along its length.

The term “electrode” is used to mean one of the two points through which electricity flows. An anode is a positive electrode and a cathode is a negative electrode.

The term “electroluminescent” or “electroactive” when referring to a layer or material, is intended to mean a layer or material that exhibits electronic or electro-radiative properties. In an electronic device, an electroactive material electronically facilitates the operation of the device. Examples of electroactive materials include, but are not limited to, materials which conduct, inject, transport, or block a charge, where the charge can be either negative (an electron) or positive (a hole), and materials which emit radiation or exhibit a change in concentration of electron-hole pairs when receiving radiation. Examples of inactive materials include, but are not limited to, insulating materials and environmental barrier materials.

The term “electronic device” or sometimes “organic electronic device” is intended to mean a device including one or more organic semiconductor layers or materials.

The term “electron transport” or “electron injection” means, when referring to a layer, material, member or structure, such a layer, material, member or structure that promotes or facilitates migration of negative charges through such a layer, material, member or structure into another layer, material, member or structure.

The term “hole injecting” is synonymous with “electron withdrawing.” Literally, holes represent a lack of electrons and are typically formed by removing electrons, thereby creating an illusion that positive charge carriers, called holes, are being created or injected. The holes migrate by a shift of electrons, so that an area with a lack of electrons is filled with electrons from an adjacent layer, which give the appearance that the holes are moving to that adjacent area. For simplicity, the terms holes, hole injecting, hole transport, and their variants will be used.

The term “hole transport” when referring to a layer, material, member, or structure, is intended to mean such layer, material, member, or structure facilitates migration of positive charges through the thickness of such layer, material, member, or structure with relative efficiency and small loss of charge.

The term “ink” is used to describe a liquid for printing, where the liquid can be a solution, dispersion, or suspension.

The term “liquid” is intended to include single liquid materials, combinations of liquid materials, and these may be solutions, dispersions, suspensions and emulsions.

The term “pixel” is intended to mean the smallest complete, repeating unit of an array. The term “subpixel” is intended to mean a portion of a pixel that makes up only a part, but not all, of a pixel. In a full-color display, a full-color pixel can comprise three sub-pixels with primary colors in red, green and blue spectral regions. A monochromatic display may include pixels but no subpixels. A sensor array can include pixels that may or may not include subpixels.

The term “slot die coating” is one of the basic methods of applying a liquid material to a “substrate” or “backplane.” Most simply, a coating liquid is forced out from a reservoir through a slot by pressure, and transferred to a moving substrate or backplane. In practice, the slot is generally much smaller in section than the reservoir, and is oriented perpendicular to the direction of substrate or backplane movement.

Slot Die coating has many variations, including design of the die itself, orientation of the die to the substrate or backplane, distance from the die to the substrate or backplane (“slot die coating” versus “extrusion coating” and “curtain coating”), “on roll” versus “off roll”, “patch coating” versus “continuous coating”, “stripe coating”, and the method of generating the pressure which forces liquid out of the die.

The term “substrate” is used to describe a surface upon which electronic elements are located to produce a backplane.

The term “surface tension” refers to the cohesive forces in a liquid, as measured in dyne/cm. As the surface tension of liquids decreases, the liquids spread more readily over a surface.

The term “thickness” is used to describe the vertical dimension of the layer upon a substrate or backplane. The vertical dimension is along a vector normal to the surface of the substrate or backplane.

The term “topographical feature” refers to raised elements located upon the top surface of a substrate or backplane.

In this specification, unless explicitly stated otherwise or indicated to the contrary by the context of usage, where an embodiment of the subject matter hereof is stated or described as comprising, including, containing, having, being composed of or being constituted by or of certain features or elements, one or more features or elements in addition to those explicitly stated or described may be present in the embodiment. An alternative embodiment of the disclosed subject matter hereof is described as consisting essentially of certain features or elements, in which embodiment features or elements that would materially alter the principle of operation or the distinguishing characteristics of the embodiment are not present therein. A further alternative embodiment of the described subject matter hereof is described as consisting of certain features or elements, in which embodiment, or in insubstantial variations thereof, only the features or elements specifically stated or described are present.

Also, use of “a” or “an” are employed to describe elements and components described herein. This is done merely for convenience and to give a general sense of the scope of the invention. This description should be read to include one or at least one and the singular also includes the plural unless it is obvious that it is meant otherwise.

Unless otherwise defined, all technical and scientific terms used herein have the same meaning as commonly understood by one of ordinary skill in the art to which this invention belongs. Although methods and materials similar or equivalent to those described herein can be used in the practice or testing of embodiments of the present invention, suitable methods and materials are described below. In case of conflict, the present specification, including definitions, will control. In addition, the materials, methods, and examples are illustrative only and not intended to be limiting.

To the extent not described herein, many details regarding specific materials, processing acts, and circuits are conventional and may be found in textbooks and other sources within the organic light-emitting diode display, photodetector, photovoltaic cell, and semiconductive member arts.

Description of Backplane Device and Process

Throughout the following detailed description similar reference characters refers to similar elements in all figures of the drawings.

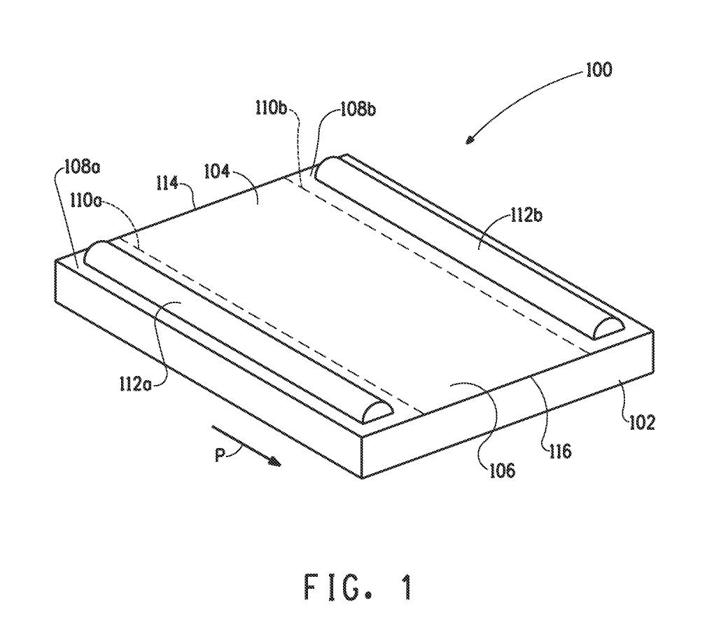

FIG. 1 represents an embodiment of the present invention with an electronic device 100 having a backplane 102. The backplane 102 has a top surface 104, and this top surface 104 contains a display area 106, and non-display area 108. Where non-display area 108 has a first side 108a and a second side 108b. A dividing line 110a is present between display area 106 and first side 108a, while dividing line 110b is present between display area 106 and second side 108b. A first topographical feature 112a is shown within first side 108a, and a second topographical feature 112b is shown within second side 108b. Many materials can be used to produce the topographical feature, including organic or inorganic materials, and the physical containment of the liquid composition is the functional requirement of the topographical feature. A printing direction is indicated by a vector P from the front 114 to the back 116 of top surface 104 of backplane 102. When the printing direction is reversed the direction of the vector P will also reverse, and front 114 and back 116 will also reverse in accordance with the vector P.

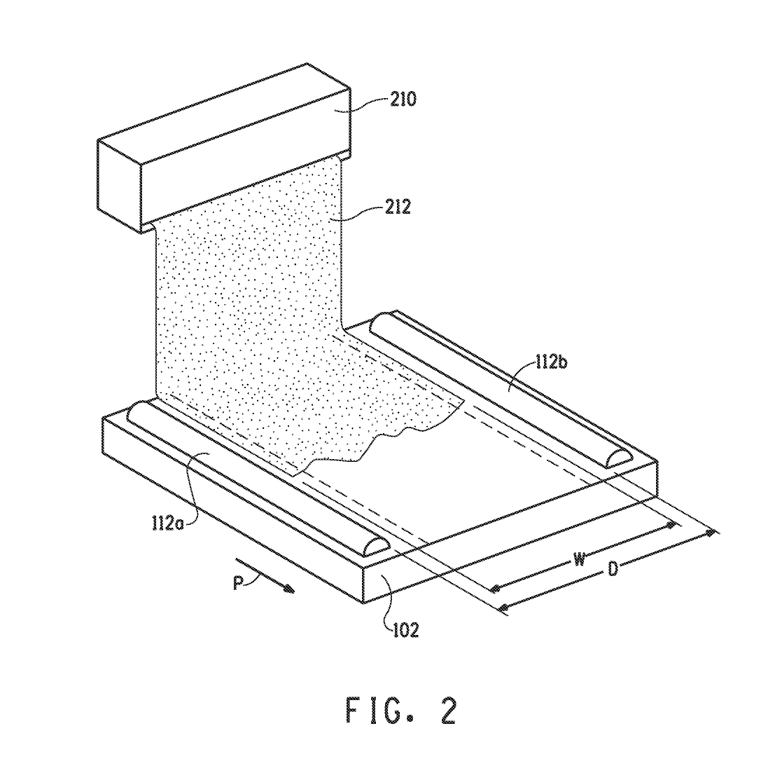

FIG. 2 represents an embodiment of the present invention where a continuous printer 210 dispenses a continuous web 212 of liquid composition onto backplane 102. Continuous liquid printing, or coating, can be accomplished by a number of methods including extrusion, curtain, screen, and slot die, using printing heads commonly associated with these methods. In at least one embodiment the continuous printer 210 is a slot die printer. The continuous web 212 contacts the backplane 102 in an area having a width W, where W spans all of the display area 106, and at least a portion of each of non-display areas 108a and 108b. In at least one embodiment, the first and second topographical features 112a and 112b, respectively, are parallel to one another and are separated by a distance D. As illustrated in FIG. 2, W is less than D, and the liquid composition will flow toward, and contact, the first and second topographical features 112a and 112b. In at least one embodiment, W is equal to D (not shown), and the liquid composition will remain in contact with the first and second topographical features 112a and 112b. In at least one embodiment, W is greater than D (not shown), and the liquid composition will contract to occupy the width D in contact with the first and second topographical features 112a and 112b. The flow behavior of the liquid composition is dependent upon many factors, with contact angle (discussed below) used to describe interaction of surface tension of liquid in relation to surface tension of surface upon which the liquid is deposited. The spreading or contraction of a liquid on a surface can be characterized by contact angle.

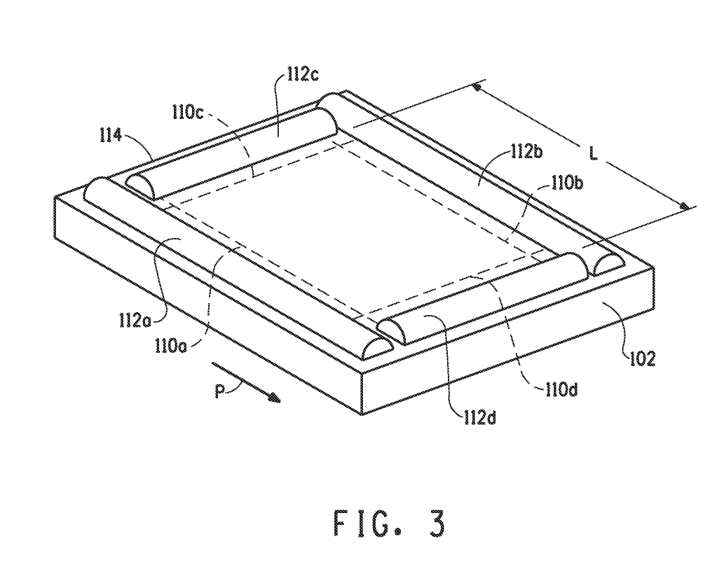

FIG. 3 represents an embodiment of the present invention where a third topographical feature 112c is located near front 114, and a fourth topographical feature 112d is located near back 116. The same discussion of liquid flow to contact the third and fourth topographical features 112c and 112d, respectively, relative to FIG. 2 also applies to FIG. 3. In addition, a dividing line 110c is present between display area 106 and front 114, while a dividing line 110d is present between display area 106 and back 116. After printing and drying of the active material, the non-display areas, bordered by dividing lines 110a, 110b, 110c, and 110d, can be removed to yield backplane 102 containing display area 106.

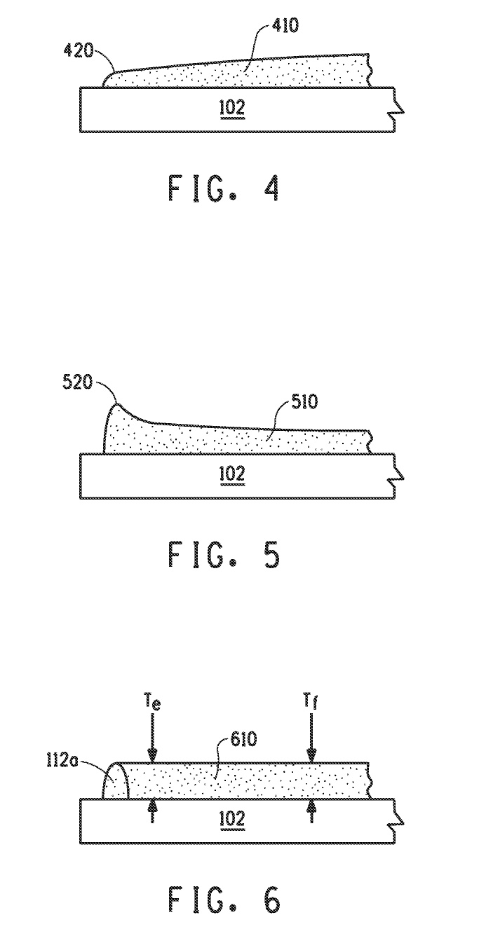

FIG. 4 represents deleterious edge effects when topographical features are not used. A dried film 410 contains a thin edge 420 resulting from solvent evaporation, and a decreased solids concentration, from the liquid composition.

FIG. 5 represents deleterious edge effects when topographical features are not used. A dried film 510 contains a thick edge 520 resulting from solvent evaporation, and an increased solids concentration, from the liquid composition.

FIG. 6 represents an embodiment of the present invention where a dried film 610 contacts the first topographical feature 112a to form an edge thickness Tₑ which has a value of plus or minus 20 percent of an average of film thickness T_{f} measurements, where T_{f} measurements are taken at points across dried film 610.

Description of Contact Angle

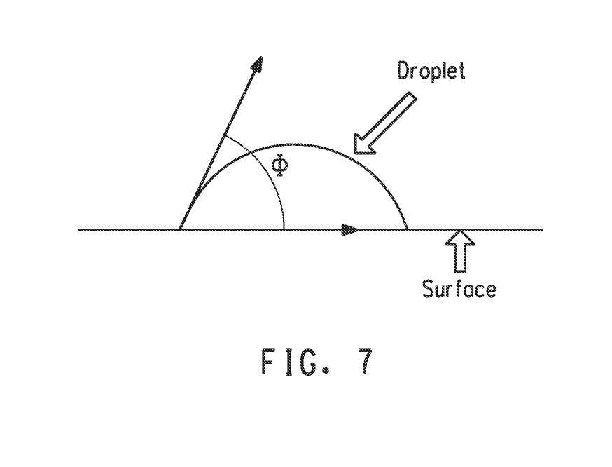

One way to determine the relative surface energies, is to compare the contact angle of a given liquid on a layer. As used herein, the term “contact angle” is intended to mean the angle φ shown in FIG. 7. For a droplet of liquid medium, angle φ is defined by the intersection of the plane of the surface and a line from the outer edge of the droplet to the surface. Furthermore, angle φ is measured after the droplet has reached an equilibrium position on the surface after being applied, i.e. “static contact angle”. A variety of manufacturers make equipment capable of measuring contact angles.

Description of Electronic Device

Devices for which the printing method described herein can be used include organic electronic devices. An organic electronic device includes, but is not limited to: (1) a device that converts electrical energy into radiation (e.g., a light-emitting diode, light emitting diode display, diode laser, or lighting panel), (2) a device that detects a signal using an electronic process (e.g., a photodetector, a photoconductive cell, a photoresistor, a photoswitch, a phototransistor, a phototube, an infrared (“IR”) detector, or a biosensors), (3) a device that converts radiation into electrical energy (e.g., a photovoltaic device or solar cell), (4) a device that includes one or more electronic components that include one or more organic semiconductor layers (e.g., a transistor or diode), or any combination of devices in items (1) through (4).

In such devices, an organic active layer is sandwiched between two electrical contact layers. At least one of the electrical contact layers is light-transmitting so that light can pass through the electrical contact layer. The organic active layer emits light through the light-transmitting electrical contact layer upon application of electricity across the electrical contact layers. Additional electroactive layers may be present between the light-emitting layer and the electrical contact layer(s).

It is well known to use organic electroluminescent compounds as the active component in such devices to provide the necessary colors. The printing method described herein is suitable for the printing of liquid compositions containing electroluminescent materials having different colors. Such materials include, but are not limited to, small molecule organic fluorescent compounds, fluorescent and phosphorescent metal complexes, conjugated polymers, and mixtures thereof. Examples of fluorescent compounds include, but are not limited to, chrysenes, pyrenes, perylenes, rubrenes, coumarins, anthracenes, thiadiazoles, derivatives thereof, and mixtures thereof. Examples of metal complexes include, but are not limited to, metal chelated oxinoid compounds, such as tris(8-hydroxyquinolato)aluminum (Alq3); cyclometalated iridium and platinum electroluminescent compounds, such as complexes of iridium with phenylpyridine, phenylquinoline, or phenylpyrimidine ligands as disclosed in Petrov et al., U.S. Pat. No. 6,670,645 and Published PCT Applications WO 03/063555 and WO 2004/016710, and organometallic complexes described in, for example, Published PCT Applications WO 03/008424, WO 03/091688, and WO 03/040257, and mixtures thereof. In some cases the small molecule fluorescent or organometallic materials are deposited as a dopant with a host material to improve processing and/or electronic properties. Examples of conjugated polymers include, but are not limited to poly(phenylenevinylenes), polyfluorenes, poly(spirobifluorenes), polythiophenes, poly(p-phenylenes), copolymers thereof, and mixtures thereof.

To form the printing inks, the above materials are dissolved or dispersed in a suitable liquid composition. A suitable solvent for a particular compound or related class of compounds can be readily determined by one skilled in the art. For some applications, it is desirable that the compounds be dissolved in non-aqueous solvents. Such non-aqueous solvents can be relatively polar, such as C₁ to C₂₀ alcohols, ethers, and acid esters, or can be relatively non-polar such as C₁ to C₁₂ alkanes or aromatics such as toluene, xylenes, trifluorotoluene and the like. Other suitable liquids for use in making the liquid composition, either as a solution or dispersion as described herein, comprising the new compounds, includes, but not limited to, chlorinated hydrocarbons (such as methylene chloride, chloroform, chlorobenzene), aromatic hydrocarbons (such as substituted and non-substituted toluenes and xylenes), including triflurotoluene), polar solvents (such as tetrahydrofuran (THP), N-methyl pyrrolidone) esters (such as ethylacetate) alcohols (isopropanol), keytones (cyclopentatone) and mixtures thereof. Suitable solvents for photoactive materials have been described in, for example, published PCT application WO 2007/145979.

The OLED device has a first electrical contact layer, which is an anode layer, and a second electrical contact layer, which is a cathode layer. A photoactive layer is between them. Additional layers may optionally be present. Adjacent to the anode may be a buffer layer. Adjacent to the buffer layer may be a hole transport layer, comprising hole transport material. Adjacent to the cathode may be an electron transport layer, comprising an electron transport material. As an option, devices may use one or more additional hole injection or hole transport layers next to the anode and/or one or more additional electron injection or electron transport layers next to the cathode.

It should be appreciated from the foregoing description that the present invention serves to form a continuous uniform layer of ink, from a continuous liquid dispenser, onto a substrate or backplane containing topographical features. The resultant display areas exhibit improved uniformity and quality, leading to improved performance of the electronic device produced from the printed and subsequently dried liquid.

Those skilled in the art, having the benefit of the teachings of the present invention, may impart modifications thereto. Such modifications are to be construed as lying within the scope of the present invention, as defined by the appended claims.

What is claimed is:

1. A printing process comprising:
providing a backplane having a top surface with display areas and non-display areas, the backplane also having a first side and a second side;
providing at least one topographical feature in the non-display area on the first side of the backplane; and
depositing an active material on display areas and at least a portion of the non-display areas, wherein the active material contacts the topographical feature to produce an edge thickness of the active material within plus-or-minus 20 percent of average thickness of active material.

2. The printing process of claim 1, further comprising a second topographical feature in the non-display area of the second side of the backplane.

3. The printing process of claim 2, further comprising a third topographical feature in the non-display area at a front side of the backplane.

4. The printing process of claim 3, further comprising a fourth topographical feature in the non-display area at a back side of the backplane.

5. The printing process of claim 2, wherein depositing uses a continuous printer.

6. The printing process of claim 5, wherein the continuous printer is a slot die coater.

7. The printing process of claim 6, wherein the first and second topographical features are parallel to one another, and distance D defines the distance between inner edges of the first and the second topographical features.

8. The printing process of claim 7, wherein slot die coater deposits a web of the active material, wherein the web has a width W upon contact with the backplane.

9. The printing process of claim 8, wherein W is equal to D.

10. The printing process of claim 8, wherein W is greater than D.

11. The printing process of claim 8, wherein W is less than D.

12. An electronic device comprising:
a backplane having a top surface with display areas and non-display areas, the backplane also having a first side and a second side;
at least one topographical feature in the non-display area on the first side of the backplane; and
an active material covering display areas and at least a portion of the non-display areas, wherein the active material contacts the topographical feature to produce an edge thickness of the active material within plus-or-minus 20 percent of average thickness of active material.

13. The electronic device of claim 12 further comprising a second topographical feature in the non-display area of the second side of the backplane.

14. The electronic device of claim 13 wherein the non-display areas are removed from the backplane.
